(19) United States
(12) Patent Application Publication
(10) Pub. No.: US 2010/0150378 A1
(43) Pub. Date: Jun. 17, 2010

(54) METHOD AND APPARATUS FOR AUDIO SIGNAL CONTROL

(75) Inventors: Jun Soo LEE, Gyeonggi-do (KR); Yoon Hark OH, Gyeonggi-do (KR); Chul Min CHOI, Seoul (KR); Eung Chan KIM, Gyeonggi-do (KR); Jong Hyun LEE, Gyeonggi-do (KR); Jun Tae LEE, Seoul (KR); Kato NAOYUKI, Gyeonggi-do (KR); Jong Sung JOO, Seoul (KR)

Correspondence Address: CHA & REITER, LLC, 210 ROUTE 4 EAST STE 103, PARAMUS, NJ, 07652, US

(73) Assignee: SAMSUNG ELECTRONICS CO., LTD., Gyeonggi-Do (KR)

(21) Appl. No.: 12/640,652

(22) Filed: Dec. 17, 2009

(30) Foreign Application Priority Data
Dec. 17, 2008 (KR) 10-2008-0128239

(51) Int. Cl. H03G 3/00

(52) U.S. Cl. 381/104

(57) ABSTRACT

An audio signal control method and apparatus for hearing protection are disclosed. The audio signal control method includes: producing an output level of an audio signal being input; determining whether the ratio of an output time of the audio signal within a preset time duration to a permissible time corresponding to the produced output level is greater than or equal to a limit reference value; and limiting, when the ratio of the output time to the permissible time is greater than or equal to the limit reference value, the output level of the audio signal to a preset level.

### CLAIMS OF PRIORITY

This application claims priority to an application entitled “METHOD AND APPARATUS FOR AUDIO SIGNAL CONTROL” filed in the Korean Intellectual Property Office on Dec. 17, 2008 and assigned Serial No. 10-2008-0128239, the contents of which are incorporated herein by reference.

### BACKGROUND OF THE INVENTION

1. Field of the Invention

The present invention relates generally to audio signal control protocol and, more particularly, to an audio signal control method and apparatus for providing a hearing protection.

2. Description of the Related Art

With advances in technologies, many portable devices such as mobile terminals support playback of multimedia files such as audio and video files. While in motion, many users enjoy the replay of music from their mobile terminals through headsets or earphones. During a replay of music via an earphone, the users tend to raise the sound volume to enhance their enjoyment of vivid or dynamic sounds. However, an audio signal (such as music sound) at a high sound pitch delivered to the ear may cause serious damage to hearing ability.

Many countries including South Korea, the United States of America, England, and Japan have similar regulations on occupational safety related to noise exposure. For example, the U.S. Department of Labor's Occupational Safety and Health Administration (OSHA) requires the employer to implement a special hearing conservation program whenever employee noise exposures equal or exceed an 8-hour time-weighted average sound level (TWA) of 85 decibels measured on the A scale (85 dBA).

Efforts are made to provide portable devices with mechanisms to comply with the noise exposure regulation and to protect worker's hearing from excessive noise level that lasts longer than a recommended time duration.

A similar protection is desirable to portable device users as many started to experience hearing problems. As such, there is a need to develop a means to control the output audio signal of a portable device so that the user is not exposed to a too high-level of sound that may cause hearing degradation.

### SUMMARY OF THE INVENTION

The present invention has been made in view of the above problems and provides additional advantages, by providing an audio signal control method and apparatus when a fatigue index (=“exposure time”/“permissible time”) is accumulated for a preset time duration, a warning message is produced when the cumulative fatigue index exceeds a preset permissible value.

In accordance with an exemplary embodiment of the present invention, there is provided an audio signal control method including: producing an output level of an audio signal being input; determining whether the ratio of an output time of the audio signal within a preset time duration to a permissible time corresponding to the produced output level is greater than or equal to a limit reference value; and limiting, when the ratio of the output time to the permissible time is greater than or equal to the limit reference value, the output level of the audio signal to a preset level.

In accordance with another exemplary embodiment of the present invention, there is provided an audio signal control apparatus including: a sound level producer producing an output level of an audio signal being input; a signal control unit determining whether the ratio of an output time of the audio signal within a preset time duration to a permissible time corresponding to the produced output level is greater than or equal to a limit reference value; and an audio output unit limiting, when the ratio of the output time to the permissible time is greater than or equal to the limit reference value, the output level of the audio signal to a preset level.

Hereinabove, the features and advantages of the present invention are described in a relatively broad perspective to help those skilled in the art understand the present invention. Other features and advantages constituting the subject matter of the present invention will be more apparent from the following detailed description.

### BRIEF DESCRIPTION OF THE DRAWINGS

The features and advantages of the present invention will be more apparent from the following detailed description in conjunction with the accompanying drawings, in which:

FIGS. 1A to 1C are graphs depicting a process for controlling the sound pressure level of an audio signal;

FIG. 2 is a block diagram of an audio signal control apparatus according to an exemplary embodiment of the present invention;

FIG. 3 is a flow chart illustrating an audio signal control method for providing a hearing ability protection according to another exemplary embodiment of the present invention;

FIG. 4 is a diagram illustrating states transitions of hearing protection protocol;

FIG. 5 illustrates an accumulation of stimulus estimates in a moving window format;

FIG. 6 illustrates a screen representation of sound volumes according to hearing protection states; and

FIG. 7 is a flow chart of a procedure for computing stimulus estimates in the audio signal control method.

### DETAILED DESCRIPTION OF THE INVENTION

Hereinafter, exemplary embodiments of the present invention are described in detail with reference to the accompanying drawings. The same reference symbols are used throughout the drawings to refer to the same or like parts. For the purposes of clarity and simplicity, detailed descriptions of well-known functions and structures incorporated herein may be omitted to avoid obscuring the subject matter of the present invention.

The present invention relates to an audio signal control scheme that enables a user not to be exposed to a harmful noise that may damage hearing ability by controlling an output audio signal generated via an earphone, a headset, or other head phones that enable audio signals. Briefly, this is achieved by preventing audio sound at a level higher than or equal to a preset level within a predetermined time period. A detailed description will be explained hereinafter with reference to figures.

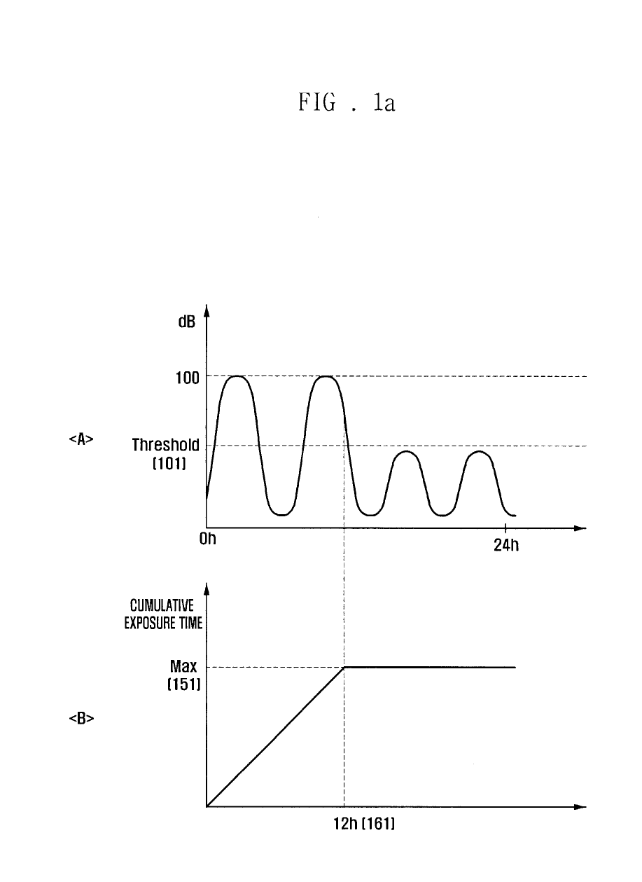

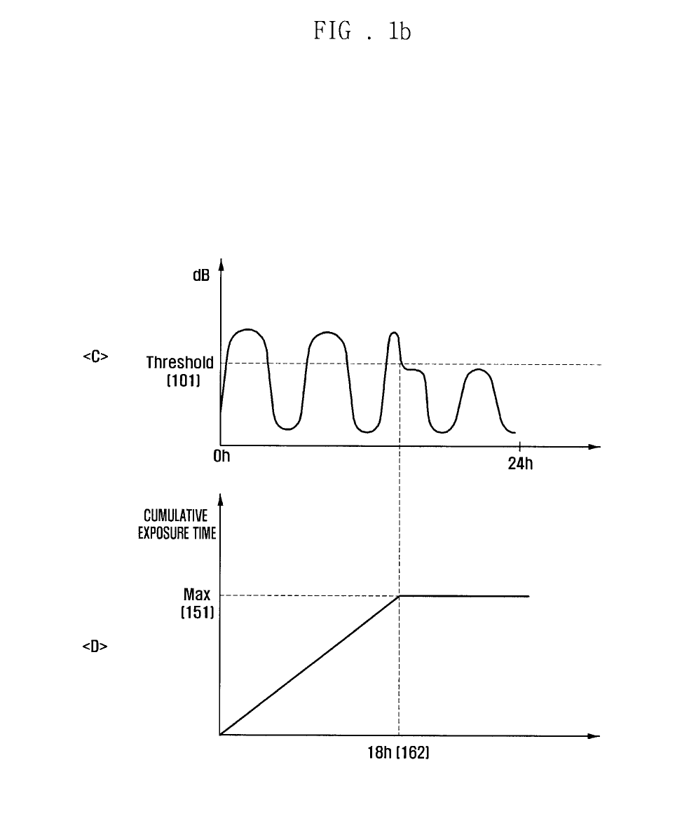

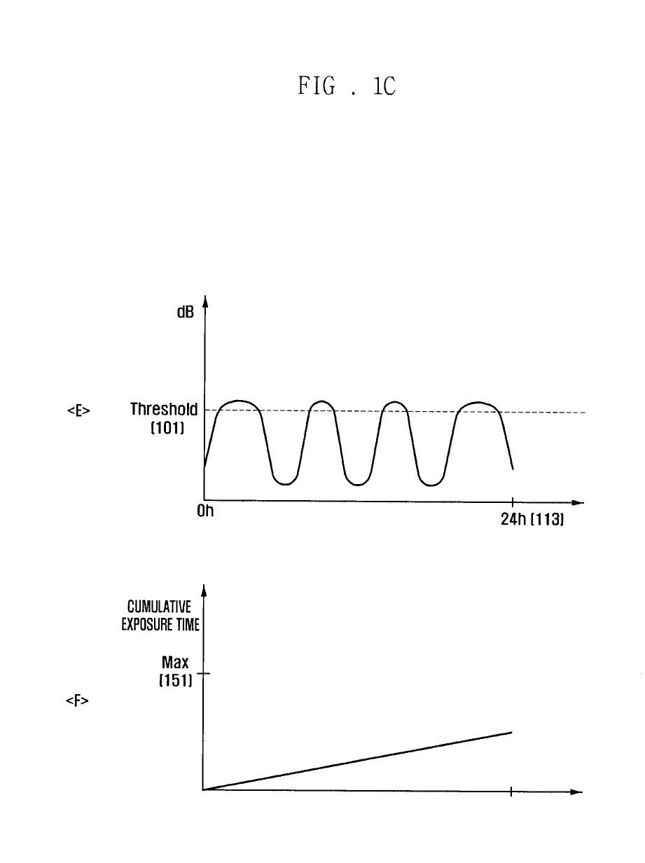

FIGS. 1A to 1C are graphs depicting a process for controlling the sound pressure level of an audio signal. In particular, FIGS. 1A to 1C depict the sound pressure levels of an audio signal output for 24 hours (0 h-24 h), where 24 hours are the criterion time duration for hearing protection according to the teachings of the present invention. However, it should be noted that 24 hour criteria is used for illustrative purposes, and other varying time limit can be set to control the sound pressure level.

As shown in FIG. 1A, graph A plots the sound pressure level of an audio signal produced from the audio output unit of a mobile terminal over time, and graph B plots the cumulative exposure time corresponding to graph A.

As known by artisians, the sound pressure level, in the unit of dBA, represents a local pressure deviation from the ambient pressure caused by a sound wave.

In graph A, a threshold value 101 indicates the lowest sound pressure level triggering a hearing conservation program specified in the noise exposure regulation in many countries, and may be 90 dBA as illustrated later in Table 1. As the criterion time duration in such a noise exposure regulation is 24 hours, the audio signal is controlled through measuring the sound pressure level higher than or equal to the threshold 101 for 24 hours. In graph B, a maximum value 151 indicates the maximum permissible exposure time limit specified in the noise exposure regulation. When the audio signal carries sounds of higher than or equal to the threshold value 101, the exposure time relative to the corresponding permissible time duration is accumulated. If the cumulative exposure time reaches the maximum value 151 at a time (in graph B, a point in time indicated by a reference numeral 161), the sound pressure level of the audio signal is limited or adjusted thereafter. Hence, after reaching the maximum value 151, though the audio signal continuously carries sounds of higher than or equal to the threshold value 101, the output sound pressure level (i.e., level when sound wave is outputted from the audio output unit a mobile terminal) is kept to a preset value less than or equal to the threshold value 101.

In FIG. 1B, graph C plots the sound pressure level of an audio signal produced from the audio output unit of a mobile terminal over time (as in the case of graph A of FIG. 1A), and graph D plots the cumulative exposure time corresponding to graph C (as in the case of graph B of FIG. 1A). A threshold value 101 of graph C indicates the lowest sound pressure level triggering a hearing conservation program specified in the noise exposure regulation in many countries, and a maximum value 151 of graph D indicates the maximum permissible exposure time limit specified in the noise exposure regulation. When the audio signal carries sounds of higher than or equal to the threshold value 101, the exposure time relative to the corresponding permissible time limit is accumulated. If the cumulative exposure time reaches the maximum value 151 at a time (in graph D, a point in time indicated by a reference numeral 162), the sound pressure level of the audio signal is limited or adjusted thereafter. Hence, after reaching the maximum value 151 at a time 162, though the audio signal continuously carries sounds of higher than or equal to the threshold value 101, the output sound pressure level is kept to a preset value less than or equal to the threshold value 101 as shown in graph C. Here, graph C shows a case where the sound pressure level of the audio signal is limited after the cumulative exposure time reaches the maximum value 151 regardless of the ending of playback of the current audio file. Alternatively, after the cumulative exposure time reaches the maximum value 151, the sound pressure level of the audio signal may be kept unchanged until playback of the current audio file ends and may be limited after the ending of the playback. In the present invention, the exposure time is accumulated only when the sound pressure level of an audio signal is higher than or equal to the threshold value 101. As the occurrence of sound pressure levels exceeding the threshold value 101 in graph C is less frequent than that in graph A, the time to reach the maximum value 151 in graph C is longer than the time to reach the maximum value 151 in graph A.

In FIG. 1C, graph E plots the sound pressure level of an audio signal produced from the audio output unit of a mobile terminal over time (as in the case of graph A of FIG. 1A or graph C of FIG. 1B), and graph F plots the cumulative exposure time corresponding to graph E (as in the case of graph B of FIG. 1A or graph D of FIG. 1B). A threshold value 101 of graph E indicates the lowest sound pressure level triggering a hearing conservation program specified in the noise exposure regulation n many countries, and a maximum value 151 of graph F indicates the maximum permissible exposure limit specified in the noise exposure regulation. When the audio signal carries sounds of higher than or equal to the threshold value 101, the exposure time relative to the corresponding permissible time is accumulated. FIG. 1C depicts a case where the sound pressure level of an audio signal is so low that the cumulative exposure time does not reach the maximum value 151 for the criterion time duration of 24 hours. In this case, the sound pressure level of the audio signal is not limited, and the user listens to sounds produced from the source audio material without change. In the present invention, the exposure time is not accumulated when the sound pressure level an audio sign is lower than the threshold value 101. Accordingly, the sound pressure level limitation is applied to only an audio signal that may cause damage to hearing ability, thereby both protecting hearing ability of the user and reducing user inconvenience due to a sound pressure level limitation.

Next, a more detailed description is given of controlling an audio signal that may cause damage to hearing ability.

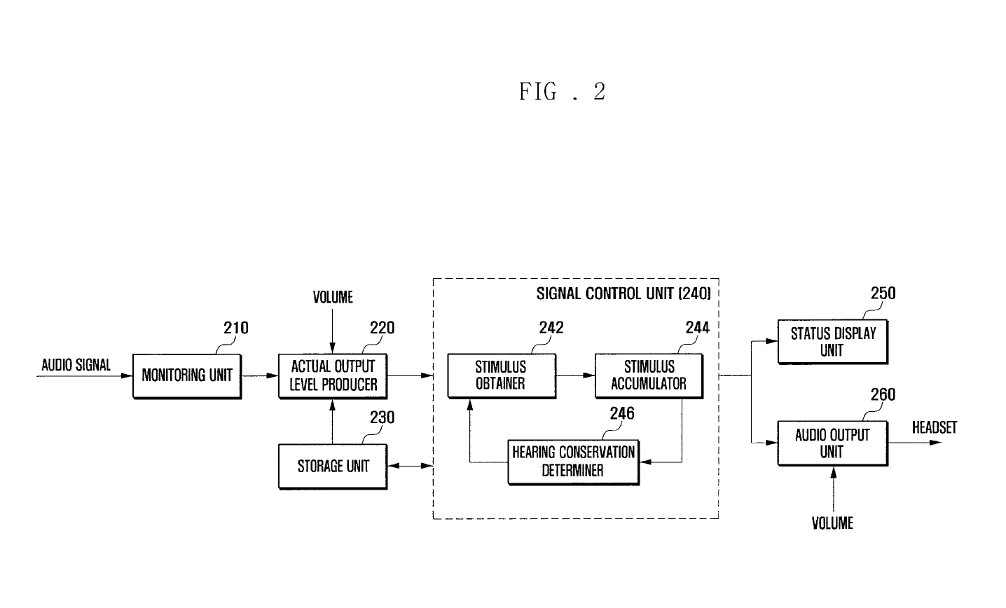

FIG. 2 is a block diagram of an audio signal control apparatus according to an exemplary embodiment of the present invention. Only components related to audio signal control are shown in FIG. 2, and other components may be included in a portable device. For example, a mobile terminal including the audio signal control apparatus may further include a communication modem for mobile communication and a camera module for photographing.

Referring to FIG. 2, the audio signal control apparatus may include a monitoring unit 210 to produce the amplitude level of a source audio material being played back relative to the maximum amplitude level possible in digital representation, a storage unit 230 to store an output sound pressure level conversion table and cumulative stimulus estimates, an actual output level producer 220 to produce the actual output sound pressure level on the basis of the output sound pressure level conversion table and the audio output volume of the mobile terminal, a signal control unit 240 to perform audio signal control by computing stimulus estimates corresponding to the sound pressure level, accumulating the stimulus estimates together into a stimulus value, and comparing the cumulative stimulus value with the threshold value, an audio output unit 260 to output a volume-controlled audio signal, and a status display unit 250 to display the stage of hearing conservation. The signal control unit 240 includes a stimulus obtainer 242 to convert the actual output sound pressure level into unit stimulus estimates Hp, a stimulus accumulator 244 to compute the cumulative stimulus value Ha, and a hearing conservation determiner 246 to determine the stage of hearing conservation and generating an output control signal.

The monitoring unit 210 determines the amplitude level of an input audio signal relative to the maximum amplitude level represented in a digital domain. For example, in the case of 16-bit representation, the maximum amplitude level is given by 32768, and 0 dBFS (decibels relative to full scale) may be assigned to the maximum possible level of 32768. The monitoring unit 210 may produce the amplitude level of the input audio signal relative to the maximum amplitude level of 32768 at every unit time. Time weighting or frequency weighting may be employed for producing the relative amplitude levels. For the purpose of description of the present invention, only A-weighting is utilized as an example of frequency weighting, but it should be noted that other weighting schemes known to artisians may be utilized. A-weighting attempts to match the response of the human ear to pure tones. A-weighting is known to those skilled in the art, and a description thereof is omitted. Briefly, A-weighting is the most commonly used of a family of curves defined in the International standard IEC 61672:2003 and various national standards relating to the measurement of sound pressure level, (see http://en.wikipedia.org/wiki/A-weighting).

The actual output level producer 220 computes, for an audio signal with a relative amplitude level determined by the monitoring unit 210, the actual sound pressure level of the audio signal at the time when the audio signal is output through an actually installed amplifier (not shown) and a headset. To compute the actual sound pressure level at the time when the audio signal is output through the audio output unit 260, the actual output level producer 220 may utilize parameters such as the volume level set in the amplifier and the sensitivity of the headset at particular frequencies. For example, when the volume level is set by the user to a high value, the actual sound pressure level at the time of output will be higher than the sound pressure level at the time of input; and when the volume level is set to a low value, the actual sound pressure level at the time of output will be lower than the sound pressure level at the time of input. When the headset tends to raise the output level of a low-frequency audio signal, the actual sound pressure level of a low-frequency audio signal will be higher than the sound pressure level at the time of input. That is, parameters affecting the sound pressure level of an audio signal may be utilized for computing the actual sound pressure level. Here, the volume level set in the amplifier corresponds to the output level of an audio signal. The sensitivity of a headset at particular frequencies corresponds to the sensitivity of the headset to an audio signal according to output levels and frequencies, and may be specified at the manufacturing process or by settings and pre-stored as a conversion table in the storage unit 230 after realistic measurement through test signals of desired characteristics.

Parameters, other than the volume level set in the amplifier or the sensitivity of a headset at particular frequencies, affecting the sound pressure level of an audio signal may also be utilized.

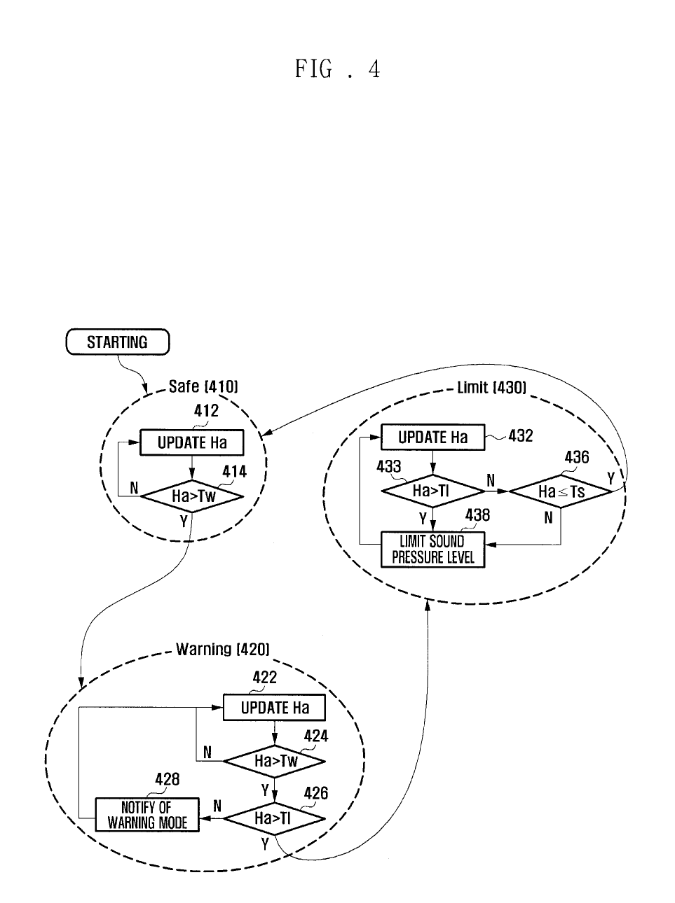

The signal control unit 240 performs audio signal control so that an audio signal with a computed actual sound pressure level higher than or equal to a preset level is not output for longer than or equal to a given time duration. To control the sound pressure level of an output audio signal, the signal control unit 240 may include a stimulus obtainer 242, a stimulus accumulator 244, and a hearing conservation determiner 246. Specifically, the stimulus obtainer 242 computes a stimulus estimate Hp for an audio signal through dividing a preset unit exposure time by the permissible time corresponding to an actual sound pressure level computed by the actual output level producer 220. The stimulus accumulator 244 computes a cumulative stimulus value Ha by accumulating multiple stimulus estimates Hp obtained for a given time duration. In the description, stimulus estimates obtained during 24 hours are accumulated. However, the duration for accumulating stimulus estimates may be altered according to the regulation or settings. The hearing conservation determiner 246 determines the stage of hearing conservation on the basis of the cumulative stimulus value from the stimulus accumulator 244, and may control the audio output unit 260 and status display unit 250 to perform an operation according to the determined stage. In the present invention, three stages including “hearing conservation off (safe mode)”, “hearing conservation warning (warning mode)”, and “hearing conservation on (limit mode)” are defined. This is described later in connection with FIG. 4. These three stages are not fixed, and may be changed if necessary. When the output sound pressure level is limited in the limit mode, the hearing conservation determiner 246 forces the stimulus obtainer 242 to generate the stimulus estimate of zero, which does not affect the stimulus value accumulation, thereby gradually decreasing the cumulative stimulus value.

The audio output unit 260 and the status display unit 250 operate according to the output of the hearing conservation determiner 246. That is, the audio output unit 260 outputs an audio signal of a sound level indicated by the output of the hearing conservation determiner 246, and the status display unit 250 provides the user with information on associations between the sound level of the output audio signal and the threshold value.

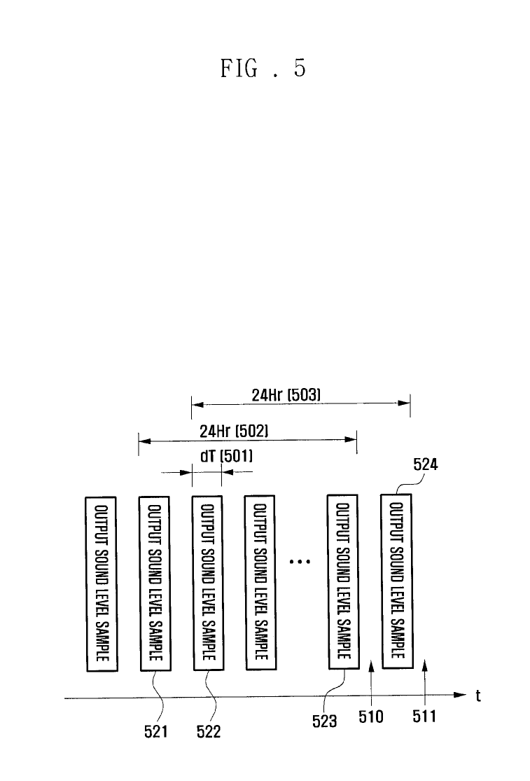

For example, the signal control unit 240 computes stimulus estimates Hp for the output sound pressure level (dBA) of an audio signal, accumulates the stimulus estimates Hp obtained during past 24 hours corresponding to sound pressure levels higher than or equal to the threshold value into a cumulative stimulus value Ha, obtains a value Hrs through normalizing the cumulative stimulus value Ha by the maximum permissible time Hmax not damaging hearing ability, and performs hearing conservation according to the value Hrs. That is, Hrs of greater than or equal to 0.8 indicates the warning mode; and Hrs of greater than or equal to 1 (exceeding the maximum permissible time) indicates the limit mode, in which the output level of the audio signal is limited for hearing conservation. In the limit mode, the stimulus estimate Hp for the output sound pressure level is set to zero, and the cumulative stimulus value Ha for 24 hours gradually decreases over time. Thereby, hearing stress is reduced. Accumulation of stimulus estimates may be effectively carried out through a moving window scheme described later in connection with FIG. 5.

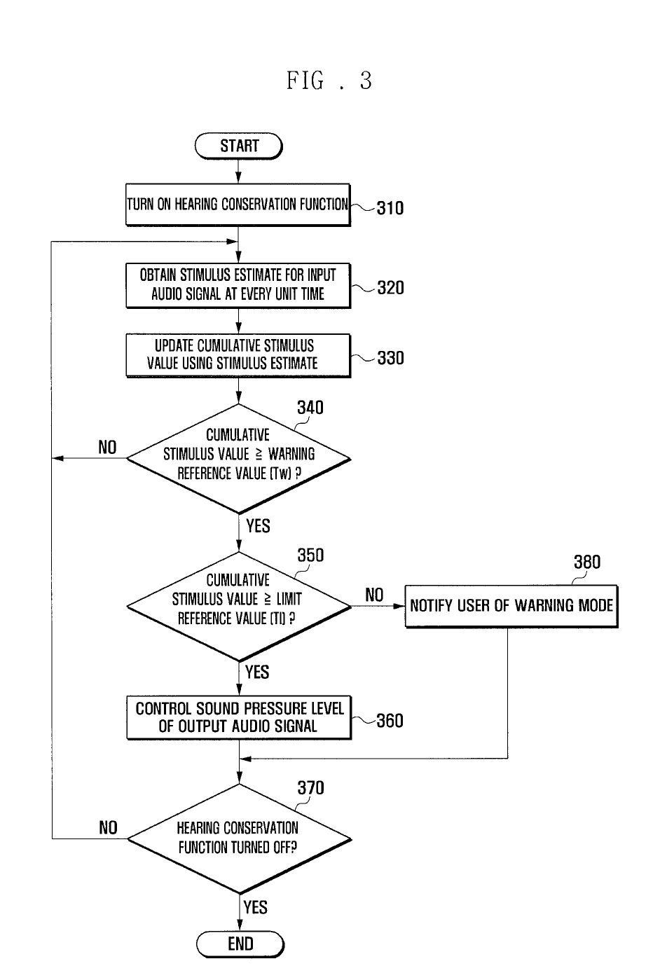

FIG. 3 is a flow chart illustrating an audio signal control method for hearing ability protection according to another exemplary embodiment of the present invention.

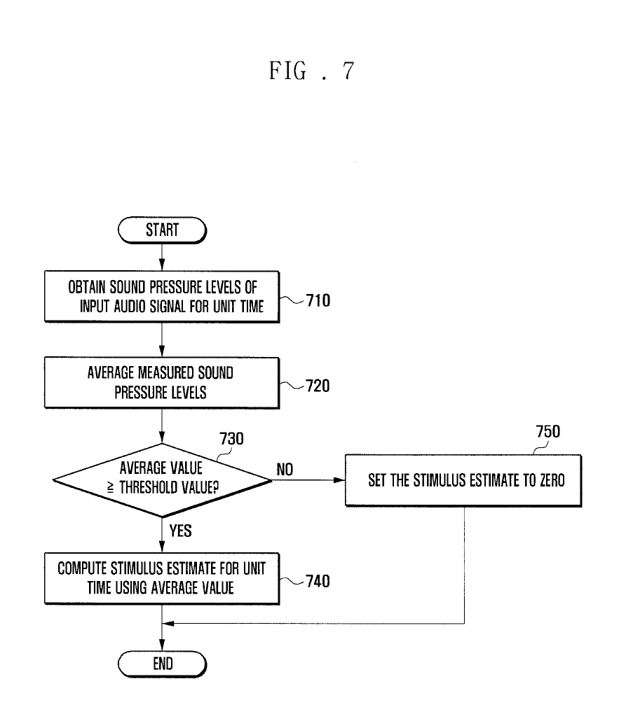

Referring to FIG. 3, when the signal control unit 240 detects turning on of the hearing conservation function (310), it obtains a stimulus estimate for the input audio signal at every preset unit time (320). For the purpose of description, it is assumed that stimulus calculation and accumulation is performed depending upon turning on or off of the hearing conservation function. However, stimulus calculation and accumulation may be continuously performed regardless of turning on or off of the hearing conservation function. Step 320 (obtaining a stimulus estimate) is described in connection with FIG. 7.

FIG. 7 is a flow chart of a procedure for computing stimulus estimates.

Referring to FIG. 7, the stimulus obtainer 242 of the signal control unit 240 obtains sound pressure levels of the input audio signal for a unit time (710). For buffering the measured sound pressure levels, the signal control unit 240 may include a buffer (not shown). Here, the unit time may correspond to a minimum playback time of an audio file acting as a source of an audio signal, and is assumed to be 6 seconds for the purpose of description. Upon expiration of the unit time (6 seconds), the stimulus obtainer 242 computes an average value by averaging the measured sound pressure levels (720). If no input audio signal is present, the average sound pressure level is set to zero.

The stimulus obtainer 242 checks whether the average value is greater than or equal to the threshold value for triggering a hearing conservation program (730). If the average value is greater than or equal to the threshold value, the stimulus obtainer 242 computes the stimulus estimate Hp for the unit time on the basis of the average value (740). Here, the average value greater than or equal to the threshold value indicates that the input audio signal carries a sound pressure level that may damage hearing ability, and may correspond to a noise level given in Table 1. The stimulus estimate (0<=Hp<=1) is computed, using Equation 1, by dividing the unit time (unit exposure time) by the permissible time corresponding to the average value (noise level).

TABLE 1

| | 1 day, permissible time (hr) | | | | | |
|---|---|---|---|---|---|---|
| | 8 | 4 | 2 | 1 | ½ | ¼ |
| Noise level (dBA) | 90 | 95 | 100 | 105 | 110 | 115 |

stimulus estimate (Hp)=unit time/permissible time (0≦Hp≦1) [Equation 1]

Table 1 indicates that exposure to an audio signal carrying a sound pressure level of 90 dBA for 8 hours or more may damage hearing ability; exposure to an audio signal carrying a sound pressure level of 95 dBA for 4 hours or more may damage hearing ability; exposure to an audio signal carrying a sound pressure level of 100 dBA for 2 hours or more may damage hearing ability; exposure to an audio signal carrying a sound pressure level of 105 dBA for 1 hour or more may damage hearing ability; exposure to an audio signal carrying a sound pressure level of 110 dBA for 30 minutes or more may damage hearing ability; and exposure to an audio signal carrying a sound pressure level of 115 dBA for 15 minutes or more may damage hearing ability. For example, when an average value of 90 dBA is obtained for a unit time of 6 seconds, the permissible time for 90 dBA is 8 hours and hence the stimulus estimate Hp is 6/28800. If the average value is less than the threshold value, the stimulus obtainer 242 sets the stimulus estimate Hp for the unit time to zero (750). A stimulus estimate of zero does not contribute to the cumulative exposure time controlling the sound level of an audio signal.

Referring back to FIG. 3, the stimulus accumulator 244 of the signal control unit 240 updates the cumulative stimulus value using the obtained stimulus estimate for the unit time (330). The cumulative stimulus value may be stored in the storage unit 230. At step 330, as shown in FIG. 5, the newly obtained stimulus estimate is added to the cumulative stimulus value, and the first stimulus estimate within the criterion time duration of 24 hours is removed.

FIG. 5 illustrates accumulation of stimulus estimates in a moving window fashion.

Referring to FIG. 5, a stimulus estimate for an input audio signal (as illustrated by graph A of FIG. 1A, graph C of FIG. 1B, or graph E of FIG. 1C) is obtained at every unit time (dT, 501), and the stimulus estimates obtained during the criterion time duration of 24 hours are accumulated into the cumulative stimulus value. For example, at a time point 510, the stimulus estimates as to output sound level samples 521 to 523 taken within 24 hours from the time point 510 are accumulated into the cumulative stimulus value. After a unit time of, for example, 6 seconds (at the time point 511), a new stimulus estimate as to a newly taken output sound level sample 524 is inserted and the stimulus estimate as to the output sound level sample 521 is deleted. Hence, at the time point 511, the stimulus estimates as to output sound level samples 522 to 524 taken within 24 hours from the time point 511 are accumulated into the cumulative stimulus value. As described above, accumulation of stimulus estimates is carried out in a moving window fashion.

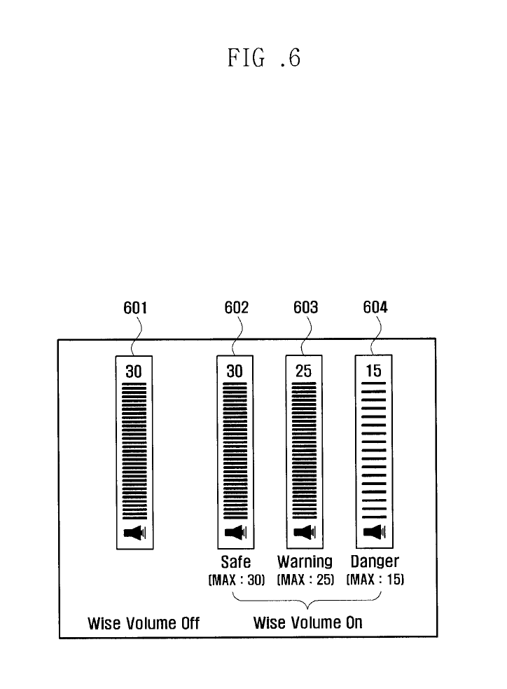

Referring back to FIG. 3, the hearing conservation determiner 246 of the signal control unit 240 checks whether the cumulative stimulus value is greater than or equal to the warning reference value Tw (340). Here, the warning reference value Tw may be preset to 0.8. If the cumulative stimulus value is less than the warning reference value Tw, the signal control unit 240 returns to step 320. If the cumulative stimulus value is greater than or equal to the warning reference value Tw, the hearing conservation determiner 246 checks whether the cumulative stimulus value is greater than or equal to the limit reference value TI (350). Here, the limit reference value TI may be preset to 1. If the cumulative stimulus value is less than the limit reference value TI, the hearing conservation determiner 246 notifies the user of the warning mode (380), and proceeds to step 370. Notification of the warning mode may be performed through the status display unit 250 as shown in FIG. 6.

FIG. 6 illustrates a screen representation of sound volumes according to states for hearing protection.

Referring to FIG. 6, the status display unit 250 displays four bars including a “wise volume off” bar 601, a “safe mode” bar 602, a “warning mode” bar 603, and a “limit mode” bar 604. The “wise volume off” bar 601 indicates that the hearing conservation function is turned off and an audio signal may be output up to a maximum volume level of 30. When the hearing conservation function is turned on, the “safe mode” bar 602 indicates that the cumulative stimulus value is less than the warning reference value and an audio signal may be output up to a maximum volume level of 30; the “warning mode” bar 603 indicates that the cumulative stimulus value is greater than or equal to the warning reference value and an audio signal may be output up to a maximum volume level of 25; the “limit mode” bar 604 indicates that the cumulative stimulus value is greater than or equal to the limit reference value and an audio signal may be output up to a maximum volume level of 15. That is, for an output audio signal, the maximum sound volume for the safe mode is higher than that for the warning mode and the maximum sound volume for the warning mode is higher than that for the limit mode. Here, volume levels of 30, 25 and 15 are simply for illustration, and may be represented by other values or colors. For example, the “safe mode” bar 602 may be set to have a blue color and a maximum volume level of 30, the “warning mode” bar 603 may be set to have a yellow color and a maximum volume level of 30, the “limit mode” bar 604 may be set to have a red color and a maximum volume level of 15.

Referring back to FIG. 3, if the cumulative stimulus value is greater than or equal to the limit reference value TI, the hearing conservation determiner 246 outputs an audio control signal for controlling the sound pressure level of the output audio signal (360). The controlled output audio signal is output at a sound pressure level lower than or equal to the threshold value. The signal control unit 240 checks whether the hearing conservation function is turned off (370). If the hearing conservation function is still turned on, the signal control unit 240 returns to step 320. If the hearing conservation function is turned off, the signal control unit 240 ends the process.

FIG. 4 is a diagram illustrating states transitions for hearing protection.

Referring to FIG. 4, in the safe mode 410, the stimulus accumulator 244 of the signal control unit 240 updates the cumulative stimulus value Ha using a new stimulus estimate Hp (412). The hearing conservation determiner 246 checks whether the cumulative stimulus value Hp is greater than the warning reference value Tw (414). If the cumulative stimulus value Hp is not greater than the warning reference value Tw, the hearing conservation determiner 246 returns to step 412. If the cumulative stimulus value Hp is greater than the warning reference value Tw, the hearing conservation determiner 246 transitions to the warning mode 422.

In the warning mode 422, the stimulus accumulator 244 of the signal control unit 240 updates the cumulative stimulus value Ha using a new stimulus estimate Hp (422). The hearing conservation determiner 246 checks whether the cumulative stimulus value Ha is greater than the warning reference value Tw (424). If the cumulative stimulus value Ha is not greater than the warning reference value Tw, the hearing conservation returns to step 422. If the cumulative stimulus value Ha is greater than the warning reference value Tw, the hearing conservation determiner 246 checks whether the cumulative stimulus value Ha is greater than the limit reference value TI (426). If the cumulative stimulus value Ha is less than the limit reference value TI, the hearing conservation determiner 246 notifies the user of the warning mode (428), and returns to step 422. If the cumulative stimulus value Ha is greater than the limit reference value TI, the hearing conservation determiner 246 transitions to the limit mode 430. As described before in connection with FIG. 6, notification of the warning mode may be performed through the status display unit 250.

In the limit mode 430, the stimulus accumulator 244 of the signal control unit 240 updates the cumulative stimulus value Ha using a new stimulus estimate Hp (432). The hearing conservation determiner 246 checks whether the cumulative stimulus value Ha is greater than the limit reference value TI (434). If the cumulative stimulus value Ha is greater than the limit reference value TI, the hearing conservation determiner 246 outputs an audio control signal for limiting the sound pressure level of the output audio signal (438), and returns to step 432. If the cumulative stimulus value Ha is not greater than the limit reference value TI, the hearing conservation determiner 246 checks whether the cumulative stimulus value Ha is less than or equal to the safe reference value Ts (436). If the cumulative stimulus value Ha is less than or equal to the safe reference value Ts, the hearing conservation determiner 246 transitions to the safe mode 410. If the cumulative stimulus value Ha is not less than or equal to the safe reference value Ts, the hearing conservation determiner 246 proceeds to step 438. Here, the safe reference value Ts may be set to 0.5, and may cause the cumulative stimulus value Ha to be decreased by a sufficient amount to suppress undesired circular transitions from the limit mode 430 to the safe mode 410 and back from the safe mode 410 to the warning mode 422 or limit mode 430.

As apparent from the above description, the present invention provides an audio signal control method and apparatus that controls the sound output level of an audio signal so that the user is not exposed to excessive noise that may damage hearing ability. The method enables real time computation of the level of exposure to sounds, and can be effectively applied to a hearing conservation device. The method and apparatus may be employed in portable devices such as a portable media player and mobile terminal for compliance to occupational safety regulations related to hearing protection. To protect hearing ability of the user, a fatigue index (=“exposure time”/“permissible time”) is accumulated for a preset time duration and a warning message is produced when the cumulative fatigue index exceeds a preset permissible value.

Although exemplary embodiments of the present invention have been described in detail hereinabove, it should be understood that many variations and modifications of the basic inventive concept herein described, which may appear to those skilled in the art, will still fall within the spirit and scope of the exemplary embodiments of the present invention as defined in the appended claims.

What is claimed is:

1. An audio signal control method comprising:
monitoring an output level of an audio signal generated via a headset;
determining whether a ratio of an output duration of the audio signal generated within a preset time period to a permissible time period for the generated output level, is greater than or equal to a limit reference value; and
limiting, when the ratio of the output duration of the audio signal to the permissible time period is greater than or equal to the limit reference value, the output level of the audio signal to a preset level.

2. The audio signal control method of claim 1, wherein determining step comprises:
calculating a stimulus estimate given by the ratio of the output duration of the audio signal to the permissible time period;
accumulating stimulus estimates obtained during the preset time period into a cumulative stimulus value; and
determining whether the cumulative stimulus value is greater than or equal to the limit reference value.

3. The audio signal control method of claim 2, wherein the calculating step comprises:
obtaining output levels of the audio signal for a unit time; and
computing a specific output level for the unit time by averaging the obtained output levels.

4. The audio signal control method of claim 2, further comprising determining whether the cumulative stimulus value is greater than or equal to a warning reference value.

5. The audio signal control method of claim 4, further comprising notifying an output audio signal limitation when the cumulative stimulus value is greater than or equal to the warning reference value.

6. The audio signal control method of claim 5, wherein notifying the user of a warning comprises displaying a warning message and limitation indication according to a predetermined format.

7. The audio signal control method of claim 2, further comprising notifying a warning related to the output level of the audio signal when the ratio of the output duration to the permissible time period is greater than or equal to the limit reference value.

8. The audio signal control method of claim 7, wherein notifying the of the output level comprises displaying an alert message and limitation indication according to a predetermined format.

9. The audio signal control method of claim 2, wherein the accumulating step is carried out according to a moving window fashion.

10. The audio signal control method of claim 2, wherein the calculating step comprises:
comparing the produced output level with a threshold level;
calculating, when the produced output level is higher than or equal to the threshold level, a stimulus estimate given by the ratio of the output duration of the audio signal to the permissible time period; and
setting, when the produced output level is lower than the threshold level, the stimulus estimate to a given value.

11. The audio signal control method of claim 2, wherein the monitoring step comprises calculating an actual output level of the audio signal on the basis of a set volume level and a sensitivity value of the headset.

12. An audio signal control apparatus comprising:
a sound level producer generating an audio signal;
a signal control unit determining whether a ratio of an output duration of the audio signal within a preset time duration to a permissible time duration for an output level of the generated audio signal is greater than or equal to a limit reference value; and
an audio output unit limiting, when the ratio of the output duration to the permissible time duration is greater than or equal to the limit reference value, the output level of the audio signal to a preset level.

13. The audio signal control apparatus of claim 12, wherein the signal control unit calculates a stimulus estimate given by the ratio of the output duration of the generated audio signal to the permissible time duration, accumulates stimulus estimates obtained during the preset time duration into a cumulative stimulus value, and determines whether the cumulative stimulus value is greater than or equal to the limit reference value.

14. The audio signal control apparatus of claim 13, wherein the signal control unit obtains output levels of the audio signal for a unit time, and computes a specific output level for the unit time by averaging the obtained output levels.

15. The audio signal control apparatus of claim 14, wherein the signal control unit determines whether the cumulative stimulus value is greater than or equal to a warning reference value, and notifies, when the cumulative stimulus value is greater than or equal to the warning reference value, a warning.

16. The audio signal control apparatus of claim 13, further comprising a status display unit displaying, when the ratio of the output duration to the permissible time duration is greater than or equal to the limit reference value, an output level limitation according to a preset format.

17. The audio signal control apparatus of claim 16, wherein the status display unit displays, when the cumulative stimulus value is greater than or equal to the warning reference value, a warning indication according to a preset format.

18. The audio signal control apparatus of claim 15, wherein the signal control unit accumulates stimulus estimates within the preset time duration in a moving window fashion.

19. The audio signal control apparatus of claim 15, wherein the signal control unit compares the output level of the audio signal with a threshold level, calculates, when the output level is higher than or equal to the threshold level, a stimulus estimate given by the ratio of the output duration of the audio signal to the permissible time duration, and sets, when the produced output level is lower than the threshold level, the stimulus estimate to a given value.

20. The audio signal control apparatus of claim 13, wherein the sound level producer calculates an actual output level of the audio signal on the basis of a set volume level and a sensitivity value of a headset.
